(19) United States
(12) Patent Application Publication
(10) Pub. No.: US 2025/0079129 A1
(43) Pub. Date: Mar. 6, 2025

(54) LINER STRUCTURE

(71) Applicant: Samsung Electronics Co., Ltd., Suwon-si (KR)

(72) Inventors: Junho LEE, Suwon-si (KR); Sangchul HAN, Suwon-si (KR); Yihwan KIM, Suwon-si (KR); Yeontae KIM, Suwon-si (KR)

(73) Assignee: Samsung Electronics Co., Ltd., Suwon-si (KR)

(21) Appl. No.: 18/420,009

(22) Filed: Jan. 23, 2024

(30) Foreign Application Priority Data
Aug. 31, 2023 (KR) 10-2023-0115090

(51) Int. Cl. H01J 37/32

(52) U.S. Cl. CPC H01J 37/32477; H01J 37/32091

(57) ABSTRACT

A liner structure may include a liner and a first block. The liner may be configured to be arranged on an inner sidewall of a reaction chamber configured to receive a heater and a substrate. The first block may be connected to the liner. The first block may include a material different from a material of the liner.

### CROSS-RELATED APPLICATION

This application claims priority under 35 USC § 119 to Korean Patent Application No. 10-2023-0115090, filed on Aug. 31, 2023 in the Korean Intellectual Property Office (KIPO), the contents of which are herein incorporated by reference in their entirety.

### BACKGROUND

### 1. Field

Example embodiments relate to a liner structure and/or an apparatus for processing a substrate including the same. More particularly, example embodiments relate to a liner structure arranged on an inner sidewall of a reaction chamber and/or an apparatus for processing a substrate including the liner structure.

### 2. Description of Related Art

Generally, an apparatus for processing a substrate may form a layer on a substrate using a plasma process. The apparatus may include a reaction chamber, a heater, a liner, etc. The reaction chamber may be configured to receive the substrate. The heater may heat the substrate. The liner may be arranged on an inner sidewall of the reaction chamber.

According to related arts, as a size of a semiconductor device may decrease, it may be required to improve uniformity of the layer on the substrate. Process improvements may be unable to achieve this requirement.

### SUMMARY

Example embodiments provide a liner structure capable of improving uniformity of a layer.

Example embodiments also provide an apparatus for processing a substrate including the above-mentioned liner structure.

According to example embodiments, a liner structure may include a liner configured to be arranged on an inner sidewall of a reaction chamber configured to receive a heater and a substrate; and a first block connected to the liner. A material of the first block may be different from a material of the liner.

According to example embodiments, a liner structure may include a liner configured to be arranged on an inner sidewall of a reaction chamber configured to receive a heater and a substrate, the liner including a plurality of receiving grooves having a same size on an inner side surface of the liner, and the liner including an insulation material; and a first block detachably received in at least one of the plurality of receiving grooves. An insulation material of the first block may be different from the insulation material of the liner.

According to example embodiments, a liner structure may include a liner configured to be arranged on an inner sidewall of a reaction chamber configured to receive a heater and a substrate, the liner including a plurality of receiving grooves having a same size on an outer side surface of the liner, and the liner including an insulation material; and a first block detachably received in at least one of the plurality of receiving grooves. The first block may include a conductive material.

According to example embodiments, a liner structure may include a first liner configured to be arranged on an inner sidewall of a reaction chamber configured to receive a heater and a substrate, the first liner including an insulation material; and a second liner configured to be arranged on the inner sidewall of the reaction chamber, the second liner being connected to ends of the first liner. An insulation material of the second liner may be different from the insulation material of the first liner.

According to example embodiments, a liner structure may include an upper liner structure configured to be arranged on an upper portion of an inner sidewall of a reaction chamber configured to receive a heater and a substrate, the an upper liner structure including an insulation material; and a lower liner structure configured to be arranged on a lower portion of the inner sidewall of the reaction chamber under the upper liner structure. The upper liner structure may include an upper liner and a first upper block. The first upper block may be connected to the upper liner. A material of the first upper block may be different from a material of the upper liner.

According to example embodiments, an apparatus for processing a substrate may include a reaction chamber configured to receive the substrate; a heater in the reaction chamber and configured to heat the substrate; a plasma generator configured to generate plasma in the reaction chamber from a reaction gas; and a liner structure on an inner sidewall of the reaction chamber. The liner structure may include a liner and a first block. The first block may be connected to the liner. A material of the first block may be different from a material of the liner.

According to example embodiments, the first block including the material different from the material of the liner may be provided to the liner to control a thickness of a layer formed on an edge portion of the substrate. Particularly, the first block may be selectively provided to the receiving grooves of the liner to locally control the thickness of the layer on the edge portion of the substrate. Thus, the layer on the substrate may have improved thickness uniformity by the liner structure.

### BRIEF DESCRIPTION OF THE DRAWINGS

Example embodiments will be more clearly understood from the following detailed description taken in conjunction with the accompanying drawings. FIGS. 1 to 12 represent non-limiting, example embodiments as described herein.

FIG. 1 is a cross-sectional view illustrating an apparatus for processing a substrate in accordance with example embodiments;

FIG. 2 is an exploded perspective view illustrating a liner structure of the apparatus in FIG. 1;

FIG. 3 is a perspective view illustrating the liner structure in FIG. 2;

FIG. 4 is a cross-sectional view illustrating an apparatus for processing a substrate in accordance with example embodiments;

FIG. 5 is a perspective view illustrating a liner structure of the apparatus in FIG. 4;

FIG. 6 is a cross-sectional view illustrating an apparatus for processing a substrate in accordance with example embodiments;

FIG. 7 is a perspective view illustrating a liner structure of the apparatus in FIG. 6;

FIG. 8 is a perspective view illustrating the liner structure in FIG. 7;

FIG. 9 is a cross-sectional view illustrating an apparatus for processing a substrate in accordance with example embodiments;

FIG. 10 is a perspective view illustrating a liner structure of the apparatus in FIG. 9;

FIG. 11 is a plan view illustrating an apparatus for processing a substrate in accordance with example embodiments; and

FIG. 12 is a cross-sectional view illustrating an apparatus for processing a substrate in accordance with example embodiments.

### DETAILED DESCRIPTION OF THE EMBODIMENTS

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, example embodiments will be explained in detail with reference to the accompanying drawings.

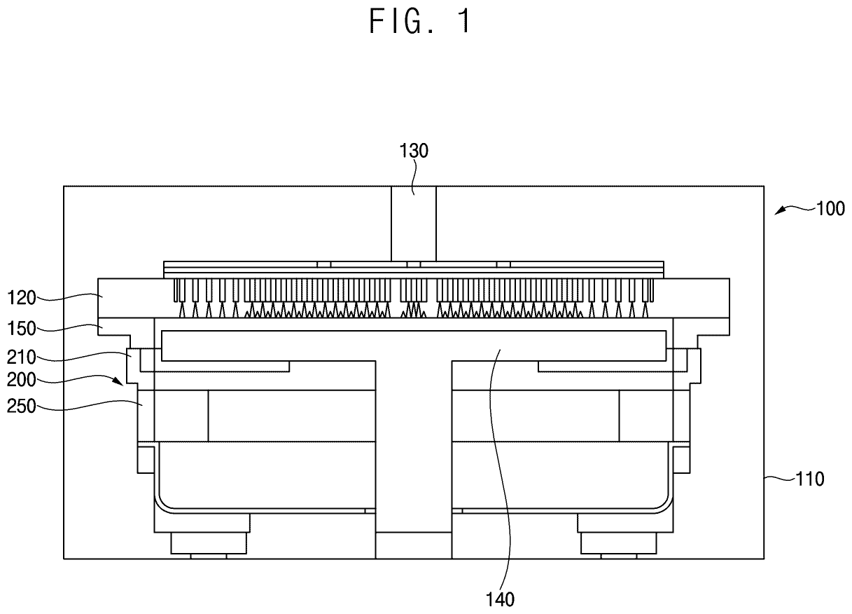

FIG. 1 is a cross-sectional view illustrating an apparatus for processing a substrate in accordance with example embodiments.

Referring to FIG. 1, an apparatus for processing a substrate in accordance with example embodiments may include a capacitively coupled plasma (CCP) type apparatus 100. The CCP type apparatus 100 may apply an RF power to opposite electrodes to generate plasma from a reaction gas using an RF electric field between the electrodes. The CCP type apparatus 100 may include semiconductor fabrication apparatuses configured to process the substrate S using the plasma in a reaction chamber such as a deposition apparatus, an etching apparatus, an ashing apparatus, etc.

The CCP type apparatus 100 may include a reaction chamber 110, a showerhead 120, a heater 140, an isolator 150, a liner structure 200, etc. That is, the CCP type apparatus 100 may include the showerhead 120 as a plasma generator.

The reaction chamber 110 may have an internal space configured to receive the substrate such as a semiconductor substrate. The reaction chamber 110 may include a vacuum region configured to define a space where the plasma may be formed from a reaction gas. A shutter may be arranged at a sidewall of the reaction chamber 110. The shutter may open and close a door through which the semiconductor substrate may be moved.

The showerhead 120 may be arranged at an upper region in the reaction chamber 110. The showerhead 120 may include a plurality of injection holes configured to inject the reaction gas into the reaction chamber 110. An RF power supply may be connected to the showerhead 120. Thus, the showerhead 120 may function as an upper electrode. A reaction gas line 130 may be connected to the showerhead 120 to supply the reaction gas into the showerhead 120.

The heater 140 may be arranged at a lower region in the reaction chamber 110. The heater 140 may include an electric-heater circuit, a lamp heater, an infrared device heater, a thermoelectric heater, but is not limited thereto. The semiconductor substrate may be placed on an upper surface of the heater 140. An RF power supply may be connected to the heater 140 so that the heater 140 may function as a lower electrode. A matcher (e.g., capacitively coupled matching circuit) may be arranged between the RF power supply and the heater 140.

The isolator 150 may be arranged on an inner sidewall of the reaction chamber 110. The isolator 150 may be positioned between the liner structure 200 and the showerhead 120. Thus, the isolator 150 may isolate the inner sidewall of the reaction chamber 110 from the space where the plasma may be formed.

The liner structure 200 may be arranged on the inner sidewall of the reaction chamber 110. The liner structure 200 may be positioned under the isolator 150. The liner structure 200 may be thermally isolate the inner sidewall of the reaction chamber 110 from heat generated from the heater 140 to provide the reaction chamber 110 with a uniform temperature. Further, the liner structure 200 may limit and/or prevent the plasma from being directly applied to the inner sidewall of the reaction chamber 110. Particularly, the liner structure 20 of example embodiments may improve thickness uniformity of a layer deposited on the semiconductor substrate.

The liner structure 200 may include an upper liner structure 210 and a lower liner structure 250. The upper liner structure 210 may be positioned under the isolator 150. The upper liner structure 210 may have a ring shape. An upper surface of the upper liner structure 210 may make contact with a lower surface of the isolator 150. The upper surface of the upper liner structure 210 may be positioned below the upper surface of the heater 140.

The lower liner structure 250 may be positioned under the upper liner structure 210. The lower liner structure 250 may have a ring shape. A diameter of the lower liner structure 250 may be the same or substantially the same as a diameter of the upper liner structure 210, but example embodiments are not limited thereto. An upper surface of the lower liner structure 250 may make contact with a lower surface of the upper liner structure 210. The lower liner structure 250 may include an insulation material. For example, the lower liner structure 250 may include aluminum oxide, but example embodiments are not limited thereto.

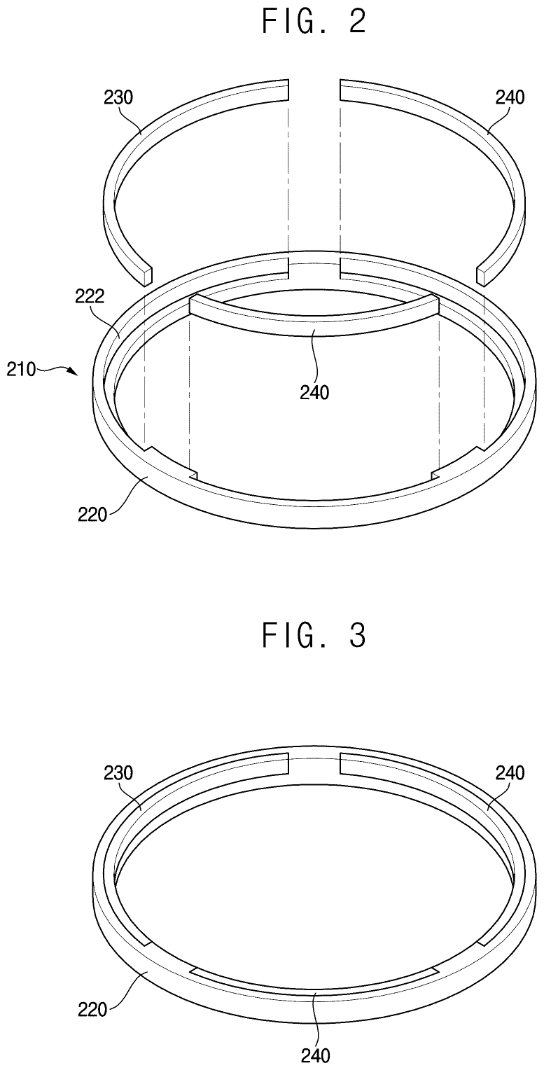

FIG. 2 is an exploded perspective view illustrating a liner structure of the apparatus in FIG. 1 and FIG. 3 is a perspective view illustrating the liner structure in FIG. 2.

Referring to FIGS. 2 and 3, the upper liner structure 210 may include an upper liner 220, at least one first upper block 230 and at least one second upper block 240.

The upper liner 220 may have a ring shape. The upper liner 220 may make contact with the inner sidewall of the reaction chamber 110. That is, an outer perimeter surface of the upper liner 220 may make contact with the inner sidewall of the reaction chamber 110. The upper liner 220 may include an insulation material. For example, the upper liner 220 may include aluminum oxide, but example embodiments are not limited thereto.

The upper liner 220 may include at least one upper receiving groove 222. The upper receiving groove 222 may be formed at an inner side surface of the upper liner 220. The upper receiving groove 222 may be formed along a circumferential line of the upper liner 220. In example embodiments, the upper receiving groove 222 may include a plurality of grooves. Further, the upper receiving grooves 222 may have the same or substantially the same size, but example embodiments are not limited thereto. The upper receiving grooves 222 may be spaced apart from each other by a uniform gap, but example embodiments are not limited thereto. In example embodiments, the upper receiving grooves 222 may be three grooves, but example embodiments are not limited thereto. For example, the upper receiving grooves 222 may be two or at least four grooves.

The first upper block 230 may be selectively provided to the upper liner 220. Particularly, the first upper block 230 may be received in at least one of the upper receiving grooves 222. The first upper block 230 may have a size corresponding to a size of the upper receiving groove 222. Particularly, the first upper block 230 may be separated from the upper receiving groove 222. The first upper block 230 in the upper receiving groove 222 may be fixed to the upper liner 220 using a fixing member. The fixing member may include a pin, but example embodiments are not limited thereto.

The first upper block 230 may include an insulation material different from the insulation material of the upper liner 220. Particularly, the first upper block 230 may have an emissivity different from an emissivity of the upper liner 220. The emissivity may correspond to an absorptivity of the heat from the heater 140. Thus, the emissivity may be inversely proportional to a temperature. That is, when the emissivity may be increased, the temperature may be decreased. In contrast, when the emissivity may be decreased, the temperature may be increased. Thus, when the first upper block 230, which may have the emissivity different from the emissivity of the upper liner 220, may be provided to the upper liner 220, a temperature of a region adjacent to the first upper block 230 may be increased or decreased. This temperature change may directly influence on the thickness of the layer deposited on the semiconductor substrate.

The temperature rise may decrease the thickness of the layer. In contrast, the temperature drop may increase the thickness of the layer. As a result, the thickness of the layer, which may be deposited on a region of an edge portion of the semiconductor substrate adjacent to the first upper block 230, may be precisely controlled to provide the layer with a uniform thickness.

In example embodiments, the emissivity of the first upper block 230 may be higher than the emissivity of the upper liner 220, but example embodiments are not limited thereto. For example, the first upper block 230 may include aluminum nitride, quartz, etc., but example embodiments are not limited thereto.

The second upper block 240 may be selectively provided to the upper liner 220. Particularly, the second upper block 240 may be received in at least one of the upper receiving grooves 222. The second upper block 240 may have a size corresponding to the size of the upper receiving groove 222. Particularly, the second upper block 240 may be separated from the upper receiving groove 222. The second upper block 240 in the upper receiving groove 222 may be fixed to the upper liner 220 using a fixing member. As mentioned above, because the upper receiving grooves 222 may have the same size, the size of the second upper block 240 may be the same or substantially the same as the size of the first upper block 230. Thus, the first upper block 230 and the second upper block 240 may be compatible with each other. Therefore, the first upper block 230 and the second upper block 240 may be selectively arranged in the upper receiving groove 222 in accordance with thicknesses of the layer on the regions of the edge portion of the semiconductor substrate.

The second upper block 240 may include an insulation material the same or substantially the same as the insulation material of the upper liner 220. Thus, the second upper block 240 may have an emissivity the same or substantially the same as the emissivity of the upper liner 220. That is, when a layer on a region adjacent to the upper receiving groove 222 may have a thickness the same or substantially the same as an average thickness of the layer on the edge portion of the semiconductor substrate, it may not be required to change the emissivity of the upper liner 220. In this case, the second upper block 240, which may have the emissivity the same or substantially the same as the emissivity of the upper liner 220, may be arranged in the upper receiving groove 222.

In contrast, the layer on the region adjacent to the upper receiving groove 222 may have a thickness different from the average thickness of the layer on the edge portion of the semiconductor substrate. Further, the thickness of the layer may also be different from a thickness of the layer on a region adjacent to the first upper block 230. In this case, the second upper block 240, which may have the emissivity different from the emissivity of the upper liner 220 and the emissivity of the first upper block 230, may be arranged in the upper receiving groove 222. Thus, the insulation material of the second upper block 240 may be different from the insulation materials of the upper liner 220 and the first upper block 230.

Therefore, when a layer formed in a previous process may have a uniform thickness, it may not be required to arrange the first upper block 230, which may include the insulation material different from the insulation material of the upper liner 220, in the upper receiving groove 222. In this case, only the second upper block 240, which may include the insulation material the same or substantially the same as the insulation material of the upper liner 220, may be arranged in the upper receiving groove 222.

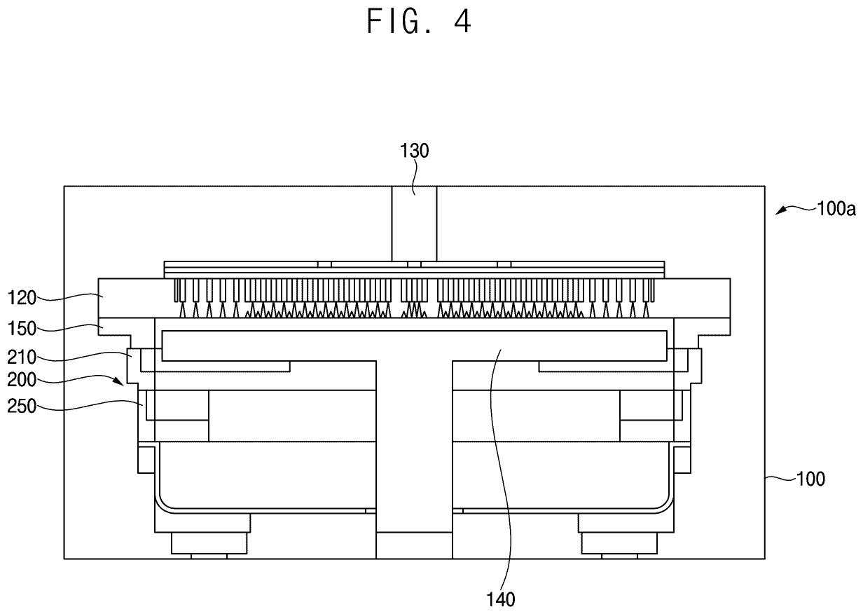

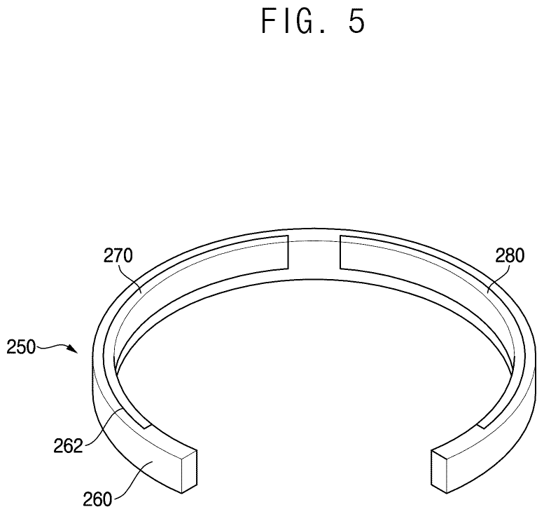

FIG. 4 is a cross-sectional view illustrating an apparatus for processing a substrate in accordance with example embodiments and FIG. 5 is a perspective view illustrating a liner structure of the apparatus in FIG. 4.

An apparatus 100a of example embodiments may include elements the same or substantially the same as those of the apparatus 100 in FIG. 1 except for a lower liner structure. Thus, the same reference numerals may refer to the same elements and any further illustrations with respect to the same elements may be omitted herein for brevity.

Referring to FIGS. 4 and 5, the lower liner structure 250 may include a lower liner 260, at least one first lower block 270 and at least one second lower block 280. That is, the lower liner structure 250 may have a structure the same or substantially the same as the structure of the upper liner structure 210 in FIGS. 2 and 3. In example embodiments, the lower liner structure 250 may not have a portion corresponding to the door of the reaction chamber 110 through which a robot arm configured to transfer the semiconductor substrate may be moved through the shutter. Thus, the lower liner structure 250 may have a shape formed by partially cutting the ring-shaped upper liner structure 210.

The lower liner 260 may have a ring shape. The lower liner 220 may include aluminum oxide, but example embodiments are not limited thereto.

The lower liner 260 may include a plurality of lower receiving groove 262. The lower receiving grooves 262 may be formed at an inner side surface of the lower liner 260. The lower receiving grooves 262 may have the same or substantially the same size, but example embodiments are not limited thereto. The lower receiving grooves 262 may be spaced apart from each other by a uniform gap, but example embodiments are not limited thereto.

The first lower block 270 may be selectively provided to the lower liner 260. Particularly, the first lower block 270 may be received in at least one of the lower receiving grooves 262. The first lower block 270 may have a shape corresponding to a shape of the lower receiving groove 262. Particularly, the first lower block 270 may be separated from the lower receiving groove 262.

The first lower block 270 may include an insulation material different from the insulation material of the lower liner 260. Particularly, the first lower block 270 may have an emissivity different from an emissivity of the lower liner 260.

In example embodiments, the emissivity of the first lower block 270 may be higher than the emissivity of the lower liner 260, but example embodiments are not limited thereto. For example, the first lower block 270 may include aluminum nitride, quartz, etc., but example embodiments are not limited thereto.

The second lower block 280 may be selectively provided to the lower liner 260. Particularly, the second lower block 280 may be received in at least one of the lower receiving grooves 262. The second lower block 280 may have a size corresponding to the size of the lower receiving groove 262. Particularly, the second lower block 280 may be separated from the lower receiving groove 262. As mentioned above, because the lower receiving grooves 262 may have the same size, the size of the second lower block 280 may be the same or substantially the same as the size of the first lower block 270. Thus, the first lower block 270 and the second lower block 280 may be compatible with each other. Therefore, the first lower block 270 and the second lower block 280 may be selectively arranged in the lower receiving groove 262 in accordance with thicknesses of the layer on the regions of the edge portion of the semiconductor substrate.

The second lower block 280 may include an insulation material the same or substantially the same as the insulation material of the lower liner 260. Thus, the second lower block 280 may have an emissivity the same or substantially the same as the emissivity of the lower liner 260. Alternatively, the emissivity of the second lower block 280 may be different from the emissivity of the lower liner 260 and the emissivity of the first lower block 270.

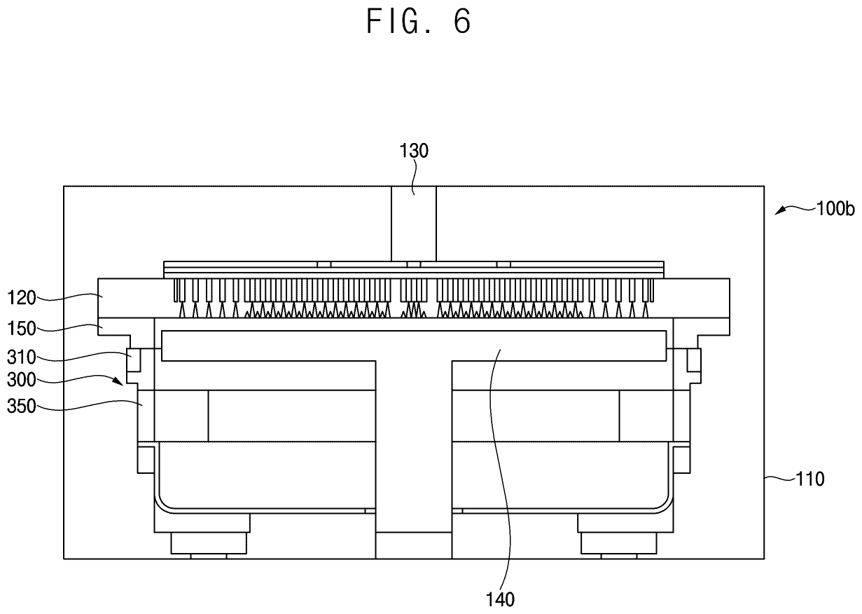

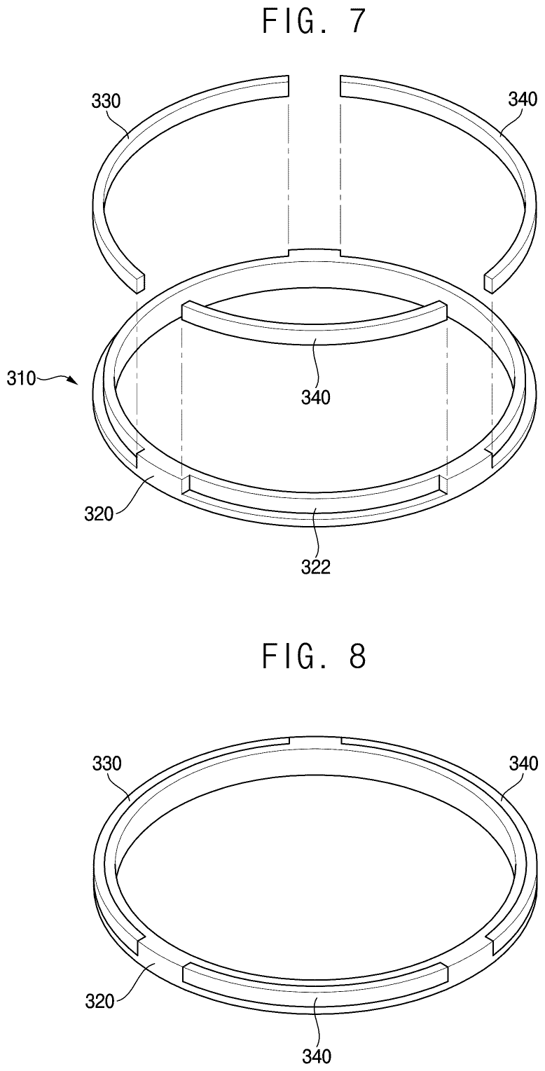

FIG. 6 is a cross-sectional view illustrating an apparatus for processing a substrate in accordance with example embodiments, FIG. 7 is a perspective view illustrating a liner structure of the apparatus in FIG. 6 and FIG. 8 is a perspective view illustrating the liner structure in FIG. 7.

An apparatus 100b of example embodiments may include elements the same or substantially the same as those of the apparatus 100 in FIG. 1 except for a liner structure. Thus, the same reference numerals may refer to the same elements and any further illustrations with respect to the same elements may be omitted herein for brevity.

Referring to FIGS. 6 to 8, an upper liner structure 310 may include an upper liner 320, at least one first upper block 330 and at least one second upper block 340.

The upper liner 320 may have a ring shape. The upper liner 320 may make contact with the inner sidewall of the reaction chamber 110. That is, an outer perimeter surface of the upper liner 320 may make contact with the inner sidewall of the reaction chamber 110. The upper liner 320 may include an insulation material. For example, the upper liner 320 may include aluminum oxide, but example embodiments are not limited thereto.

The upper liner 320 may include at least one upper receiving groove 322. The upper receiving groove 322 may be formed at an outer side surface of the upper liner 320. The upper receiving groove 322 may be formed along a circumferential line of the upper liner 320. In example embodiments, the upper receiving groove 322 may include a plurality of grooves. Further, the upper receiving grooves 322 may have the same or substantially the same size, but example embodiments are not limited thereto. The upper receiving grooves 322 may be spaced apart from each other by a uniform gap, but example embodiments are not limited thereto. In example embodiments, the upper receiving grooves 322 may be three grooves, but example embodiments are not limited thereto. For example, the upper receiving grooves 322 may be two or at least four grooves.

The first upper block 330 may be selectively provided to the upper liner 320. Particularly, the first upper block 330 may be received in at least one of the upper receiving grooves 322. Thus, the first upper block 30 may make contact with the inner sidewall of the reaction chamber 110. The first upper block 330 may have a size corresponding to a size of the upper receiving groove 322. Particularly, the first upper block 330 may be separated from the upper receiving groove 322. The first upper block 330 in the upper receiving groove 322 may be fixed to the upper liner 320 using a fixing member. The fixing member may include a pin, but example embodiments are not limited thereto.

The first upper block 330 may include a conductive material. For example, the first upper block 330 may include a metal such as aluminum, but example embodiments are not limited thereto. The first upper block 330 including the conductive material may change impedance between the showerhead 120 and the heater 140. The impedance change may induce a change of an electric field. The change of the electric field may influence on a density of the plasma. Thus, the first upper block 330 including the conductive material may have influence on the thickness of the layer deposited on the edge portion of the semiconductor substrate.

The second upper block 340 may be selectively provided to the upper liner 320. Particularly, the second upper block 340 may be received in at least one of the upper receiving grooves 322. The second upper block 340 may have a size corresponding to the size of the upper receiving groove 322. Particularly, the second upper block 340 may be separated from the upper receiving groove 322. The second upper block 340 in the upper receiving groove 322 may be fixed to the upper liner 320 using a fixing member. As mentioned above, because the upper receiving grooves 322 may have the same size, the size of the second upper block 340 may be the same or substantially the same as the size of the first upper block 330. Thus, the first upper block 330 and the second upper block 340 may be compatible with each other. Therefore, the first upper block 330 and the second upper block 340 may be selectively arranged in the upper receiving groove 322.

The second upper block 340 may include an insulation material the same or substantially the same as the insulation material of the upper liner 320. Thus, the second upper block 340 including the insulation material may not have influence on the impedance between the showerhead 120 and the heater 140.

Alternatively, the second upper block 340 may include a conductive material having conductivity different from a conductivity of the conductive material of the first upper block 330.

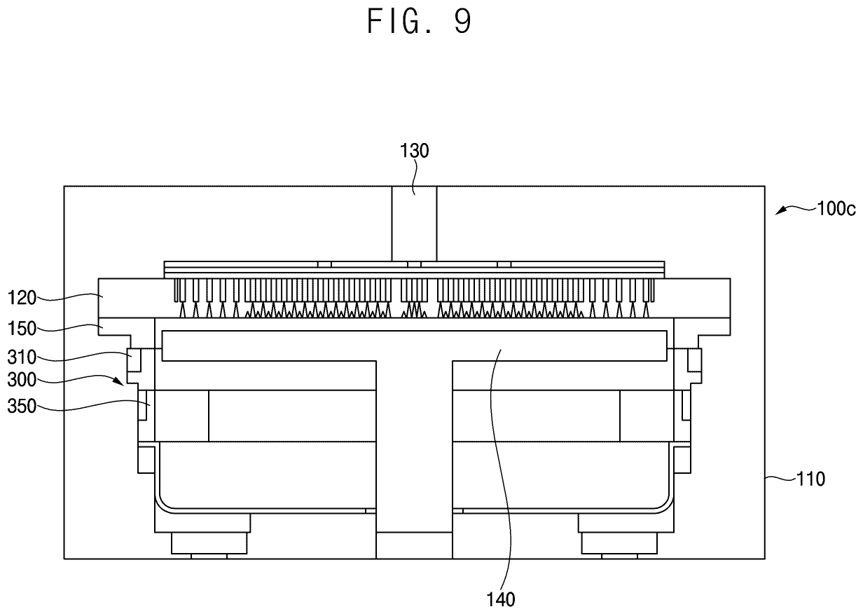

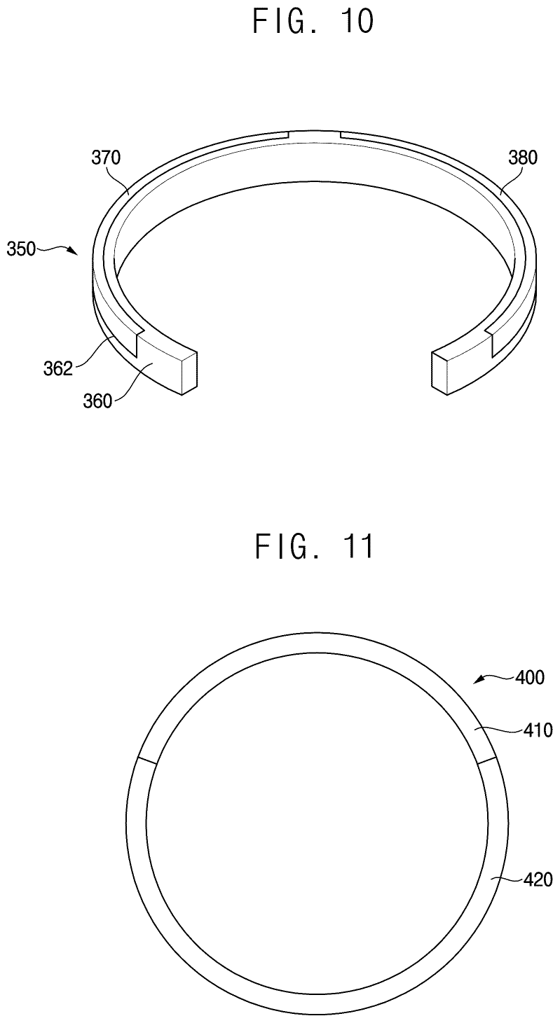

FIG. 9 is a cross-sectional view illustrating an apparatus for processing a substrate in accordance with example embodiments and FIG. 10 is a perspective view illustrating a liner structure of the apparatus in FIG. 9.

An apparatus 100c of example embodiments may include elements the same or substantially the same as those of the apparatus 100b in FIG. 6 except for a lower liner structure. Thus, the same reference numerals may refer to the same elements and any further illustrations with respect to the same elements may be omitted herein for brevity.

Referring to FIGS. 9 and 10, the lower liner structure 350 may include a lower liner 360, at least one first lower block 370 and at least one second lower block 380. That is, the lower liner structure 350 may have a structure the same or substantially the same as the structure of the upper liner structure 310 in FIGS. 7 and 8. In example embodiments, the lower liner structure 350 may not have a portion corresponding to the door of the reaction chamber 110 through which the robot arm configured to transfer the semiconductor substrate may be moved through the shutter. Thus, the lower liner structure 350 may have a shape formed by partially cutting the ring-shaped upper liner structure 310.

The lower liner 360 may have a ring shape. The lower liner 360 may make contact with the inner sidewall of the reaction chamber 110. The lower liner 360 may include an insulation material. For example, the lower liner 360 may include aluminum oxide, but example embodiments are not limited thereto.

The lower liner 360 may include a plurality of lower receiving grooves 362. The lower receiving grooves 362 may be formed at an outer side surface of the lower liner 360. The lower receiving grooves 362 may have the same or substantially the same size, but example embodiments are not limited thereto. The lower receiving grooves 362 may be spaced apart from each other by a uniform gap, but example embodiments are not limited thereto.

The first lower block 370 may be selectively provided to the lower liner 360. Particularly, the first lower block 370 may be received in at least one of the lower receiving grooves 362. The first lower block 370 may have a size corresponding to the size of the lower receiving groove 362. Particularly, the first lower block 370 may be separated from the lower receiving groove 362.

The first lower block 370 may include a conductive material. For example, the first lower block 370 may include a metal such as aluminum, but example embodiments are not limited thereto.

The second lower block 380 may be selectively provided to the lower liner 360. Particularly, the second lower block 380 may be received in at least one of the lower receiving grooves 362. The second lower block 380 may have a size corresponding to the size of the lower receiving groove 362. Particularly, the second lower block 380 may be separated from the lower receiving groove 362. As mentioned above, because the lower receiving grooves 362 may have the same size, the size of the second lower block 380 may be the same or substantially the same as the size of the first lower block 370. Thus, the first lower block 370 and the second lower block 380 may be compatible with each other. Therefore, the first lower block 370 and the second lower block 380 may be selectively arranged in the lower receiving groove 362.

The second lower block 380 may include an insulation material the same or substantially the same as the insulation material of the lower liner 360. Thus, the second lower block 380 including the insulation material may not have influence on the impedance between the showerhead 120 and the heater 140.

Alternatively, the second lower block 380 may include a conductive material having conductivity different from a conductivity of the conductive material of the first lower block 370.

FIG. 11 is a plan view illustrating an apparatus for processing a substrate in accordance with example embodiments.

Referring to FIG. 11, a liner structure 400 of example embodiments may include a first liner 410 and a second liner 420. The first liner 410 and the second liner 420 may form one ring shape. That is, the second liner 420 may be extended from both ends of the first liner 410.

The second liner 420 may include an insulation material different from an insulation material of the first liner 410. Particularly, the second liner 420 may have an emissivity higher than an emissivity of the first liner 410. In example embodiments, the first liner 410 may include aluminum oxide and the second liner 420 may include aluminum nitride, quartz, etc., but example embodiments are not limited thereto.

The first liner 410 may be positioned adjacent to the shutter. Because the shutter may open and close the door of the reaction chamber 110, a temperature of the edge portion of the semiconductor substrate adjacent to the shutter may be lower than temperatures of other portions of the semiconductor substrate. Thus, when the second liner 420 may be positioned remote from the shutter, a temperature adjacent to the second liner 420 may be decreased to the temperature adjacent to the shutter. The first liner 410 may control the temperature of the edge portion of the semiconductor substrate adjacent to the shutter. Thus, an arc length of the first liner 410 may be shorter than an arc length of the second liner 420.

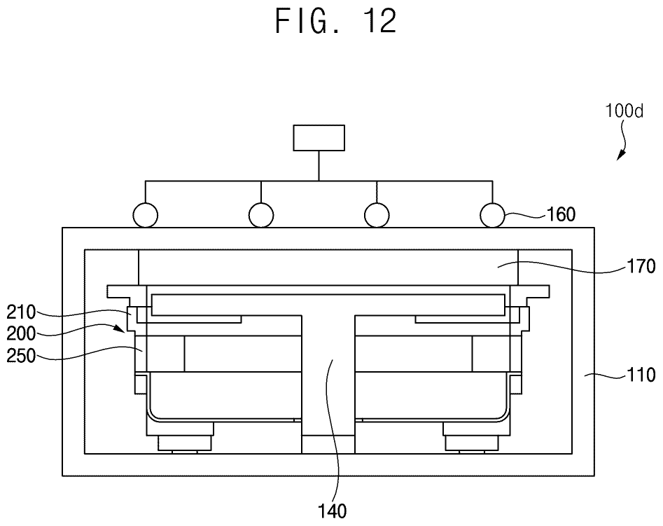

FIG. 12 is a cross-sectional view illustrating an apparatus for processing a substrate in accordance with example embodiments.

Referring to FIG. 12, an inductively coupled plasma (ICP) type apparatus 100d may generate plasma from a reaction gas using a magnetic field induced by a coil antenna 224. An RF power applied to the coil antenna 224 may be transmitted to the reaction gas through a dielectric window 220. The ICP type apparatus 100d may include semiconductor fabrication apparatuses configured to process the substrate using the plasma in a reaction chamber such as a deposition apparatus, an etching apparatus, an ashing apparatus, etc.

The ICP type apparatus 100d may include a reaction chamber 110, an antenna 160, a dielectric window 170, a heater 140 and a liner structure 200, etc. That is, the ICP type apparatus 100d may include the antenna 160 and the dielectric window 170 as the plasma generator.

The reaction chamber 110 may have an internal space configured to receive the semiconductor substrate. The reaction chamber 110 may have a vacuum region for defining a space where the plasma may be formed from the plasma.

The antenna 160 may be arranged on the upper surface of the reaction chamber 110. An RF power supply may be connected to the antenna 160. A magnetic field induced by the antenna 160 may be applied to the reaction gas injected into the reaction chamber 110 to generate the plasma.

The dielectric window 170 may be arranged under the antenna 160. The dielectric window 170 may include a dielectric material. The dielectric window 170 may transmit the RF power in the antenna 160 into the reaction chamber 110. Further, the dielectric window 170 may inject the reaction gas into the reaction chamber 110.

The heater 140 may be arranged at a lower region in the reaction chamber 110. The semiconductor substrate may be placed on an upper surface of the heater 140. An RF power supply may be connected to the heater 140 so that the heater 140 may function as a lower electrode. A matcher may be arranged between the RF power supply and the heater 140.

The liner structure 200 may be arranged on the inner sidewall of the reaction chamber 110. The liner structure 200 may be thermally isolate the inner sidewall of the reaction chamber 110 from heat generated from the heater 140 to provide the reaction chamber 110 with a uniform temperature. Further, the liner structure 200 may limit and/or prevent the plasma from being directly applied to the inner sidewall of the reaction chamber 110. Particularly, the liner structure 20 of example embodiments may improve thickness uniformity of a layer deposited on the semiconductor substrate.

In example embodiments, the liner structure 200 may have a structure the same or substantially the same as the structure of the liner structure 200 in FIGS. 2 and 3. Thus, any further illustrations with respect to the liner structure 200 may be omitted herein for brevity.

Alternatively, the liner structure 200 may have the structure in FIG. 4, the structure in FIG. 6, the structure in FIG. 9, or the structure in FIG. 11.

According to example embodiments, the first block including the material different from the material of the liner may be provided to the liner to control a thickness of a layer formed on an edge portion of the substrate. Particularly, the first block may be selectively provided to the receiving grooves of the liner to locally control the thickness of the layer on the edge portion of the substrate. Thus, the layer on the substrate may have improved thickness uniformity by the liner structure.

The foregoing is illustrative of example embodiments and is not to be construed as limiting thereof. Although a few example embodiments have been described, those skilled in the art will readily appreciate that many modifications are possible in the example embodiments without droplet departing from the novel teachings and advantages of embodiments of inventive concepts. Accordingly, all such modifications are intended to be included within the scope of inventive concepts as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A liner structure comprising:
a liner configured to be arranged on an inner sidewall of a reaction chamber configured to receive a heater and a substrate; and
a first block connected to the liner, a material of the first block being different from a material of the liner.

2. The liner structure of claim 1, wherein the first block is on an inner side surface of the liner.

3. The liner structure of claim 2, wherein
the material of the first block is an insulation material of the first block
the material of the liner is an insulation material of the liner, and
the insulation material of the first block is different from the insulation material of the liner.

4. The liner structure of claim 3, wherein an emissivity of the first block is different from an emissivity of the liner.

5. The liner structure of claim 4, wherein the emissivity of the first block is higher than the emissivity of the liner.

6. The liner structure of claim 5, wherein
the insulation material of the liner comprises aluminum oxide, and
the insulation material of the first block comprises aluminum nitride or quartz.

7. The liner structure of claim 2, wherein
the liner includes a receiving groove on the inner side surface of the liner, and
the receiving groove is configured to receive the first block.

8. The liner structure of claim 7, wherein
the receiving groove comprises a plurality of receiving grooves having a same size, and
the first block is in at least one of the plurality of receiving grooves.

9. The liner structure of claim 8, wherein the first block is detachably received in the at least one of the plurality of receiving grooves.

10. The liner structure of claim 8, further comprising:
a second block in one or more of the plurality of receiving grooves, wherein
the first block and the second block respectively are in different receiving grooves among the plurality of receiving grooves.

11. The liner structure of claim 10, wherein
a material of the second block is a same material as the material of the liner.

12. The liner structure of claim 10, wherein
a material of the second block is different from the material of the liner and the material of the first block.

13. The liner structure of claim 10, wherein the second block is detachably received in the one or more of the plurality of receiving grooves.

14-23. (canceled)

24. A liner structure comprising:
a liner configured to be arranged on an inner sidewall of a reaction chamber configured to receive a heater and a substrate, the liner including a plurality of receiving grooves having a same size on an inner side surface of the liner, and the liner including an insulation material; and
a first block detachably received in at least one of the plurality of receiving grooves, an insulation material of the first block being different from the insulation material of the liner.

25. The liner structure of claim 24, wherein an emissivity of the first block is higher than an emissivity of the liner.

26. (canceled)

27. The liner structure of claim 24, further comprising:
a second block detachably received in one or more of the plurality of receiving grooves, wherein
the first block and the second block respectively are in different receiving grooves among the plurality of receiving grooves.

28. (canceled)

29. A liner structure comprising:
a liner configured to be arranged on an inner sidewall of a reaction chamber configured to receive a heater and a substrate, the liner including a plurality of receiving grooves having a same size on an outer side surface of the liner, and the liner including an insulation material; and
a first block detachably received in at least one of the plurality of receiving grooves, the first block including a conductive material.

30. The liner structure of claim 29, wherein
the insulation material of the liner comprises aluminum oxide, and
the conductive material of the first block comprises a metal.

31. The liner structure of claim 29, further comprising:
a second block detachably received in at least one of the plurality of receiving grooves, wherein
the first block and the second block respectively are in different receiving grooves among the plurality of receiving grooves.

32. The liner structure of claim 31, wherein the insulation material of the second block comprises a same insulation material as the insulation material of the liner.

33-58. (canceled)
